(19) United States
(12) Patent Application Publication
(10) Pub. No.: US 2012/0243242 A1
(43) Pub. Date: Sep. 27, 2012

(54) LIGHTING MODULE AND POWER CONNECTING SET

(75) Inventors: Chun-Ming Lai, Yuanli Township (TW); Shih-Chin Chou, Kaohsiung City (TW); Ming-Hua Tsai, Chiayi City (TW)

(73) Assignee: LEXTAR ELECTRONICS CORPORATION, Hsinchu (TW)

(21) Appl. No.: 13/222,163

(22) Filed: Aug. 31, 2011

(30) Foreign Application Priority Data
Mar. 24, 2011 (TW) 100110196

(51) Int. Cl. F21V 19/00; H05K 1/18

(52) U.S. Cl. 362/382; 361/748

(57) ABSTRACT

A lighting module and a power connecting set are provided. The lighting module includes two circuit boards, two light emitting elements and a power connecting set. The light emitting elements are disposed on the circuit boards respectively. The power connecting set includes two connecting bases and a flexible circuit board. The connecting bases are disposed on the circuit boards and electronically connected to the circuit boards respectively. Two ends of the flexible circuit board are connected to the connecting bases for electrically connecting a power path of the circuit boards.

This application claims the benefit of Taiwan application Serial No. 100110196, filed Mar. 24, 2011, the subject matter of which is incorporated herein by reference.

### BACKGROUND OF THE INVENTION

1. Field of the Invention

The invention relates in general to a lighting module and a power connecting set, and more particularly to a lighting module connecting two circuit boards, and a power connecting set.

2. Description of the Related Art

Light emitting diodes (LED) have marked a milestone in the advance and development in the lighting technology.

Light emitting diodes, advantaged by high light emitting efficiency, long lifespan, robustness, low power consumption, small size, low pollution and low heat dissipation, have been widely used in various electronic products.

In general, light emitting diodes are disposed on a circuit board and electrically connected to the power end through the circuit board so that the light emitting diodes can be enabled accordingly.

As new electronic products are continuously provided, the shape of the circuit board and the arrangement of the light emitting diode are designed according to the needs for the electronic products. In some products, the circuit boards carrying the light emitting diodes must be connected. However, there are many problems and challenges regarding the currently used methods for connecting the circuit boards. Therefore, how to improve the method for connecting several circuit boards carrying the light emitting diode has become an imminent task for the industries.

### SUMMARY OF THE INVENTION

The invention is directed to a lighting module and a power connecting set. Through the design of the power connecting set, the circuit boards are mechanically connected, and a power path of the circuit boards is electrically connected.

According to a first aspect of the present invention, a lighting module is provided. The lighting module includes two circuit boards, two light emitting elements and a power connecting set. The light emitting elements are disposed on the circuit boards respectively. The power connecting set includes two connecting bases and a flexible circuit board. The connecting bases are disposed on the circuit boards and electronically connected to the circuit boards respectively. Two ends of the flexible circuit board are connected to the connecting bases for electrically connecting a power path of the circuit boards.

According to a second aspect of the present invention, a power connecting set is provided. The power connecting set is for connecting two circuit boards. The power connecting set includes two connecting bases and a flexible circuit board. The connecting bases are disposed on the circuit boards and electronically connected to the circuit boards respectively. Two ends of the flexible circuit board are connected to the connecting bases for electrically connecting a power path of the circuit boards.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a schematic diagram of a lighting module according to an exemplary embodiment of the invention;

FIG. 2 shows a schematic diagram of a cover of a connecting base being opened;

FIG. 3 shows a schematic diagram of a cover of a connecting base being closed;

FIG. 4 shows a schematic diagram of a lamp tube according to an alternative embodiment;

FIG. 5 shows a schematic diagram of a lamp bar according to an alternative embodiment.

### DETAILED DESCRIPTION OF THE INVENTION

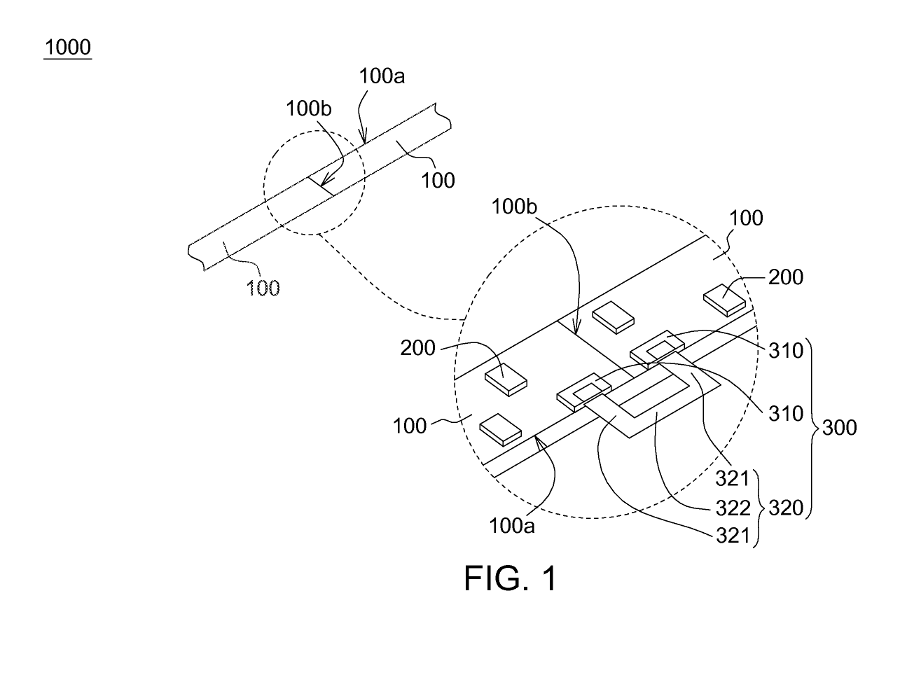

Referring to FIG. 1, a schematic diagram of a lighting module 1000 according to an exemplary embodiment of the invention is shown. The lighting module 1000 includes at least two circuit boards 100, at least two light emitting elements 200 and at least a power connecting set 300. The circuit boards 100 are used for carrying and electrically connecting various electronic elements to provide specific electrical functions. The circuit boards 100 can be realized by such as single-sided circuit boards or double-sided circuit boards. The light emitting elements 200 are disposed on each of the circuit boards 100 respectively for emitting a light and can be realized by such as light emitting diodes (LEDs). The power connecting set 300 is for connecting the circuit boards 100 and electrically connecting a power path of the light emitting elements 200. Each of the power connecting sets 300 includes two connecting bases 310 and a flexible circuit board 320. Two connecting bases 310 are disposed on the circuit boards 100 and electronically connected to the circuit boards 100 respectively. Two ends of the flexible circuit board 320 are connected to the connecting bases 310 for electrically connecting the power path of the circuit boards 100.

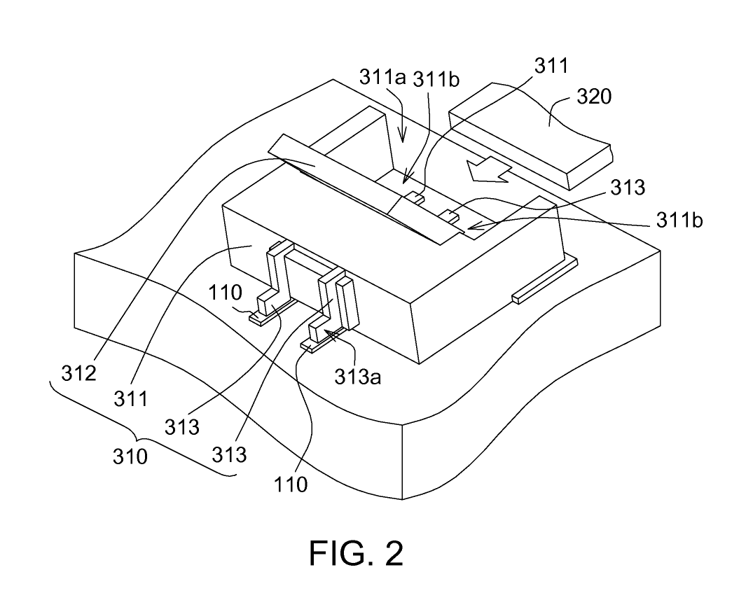

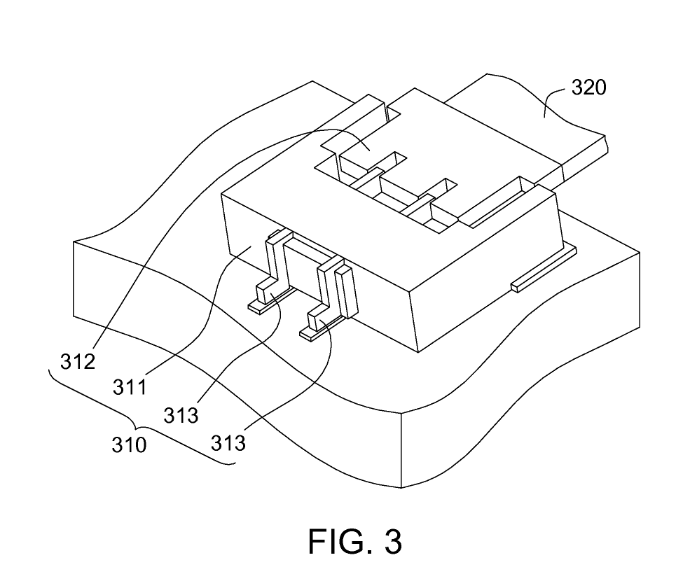

Referring to FIGS. 2 to 3. FIG. 2 shows a schematic diagram of a cover 312 of a connecting base 310 being opened. FIG. 3 shows a schematic diagram of a cover 312 of a connecting base 310 being closed. The connecting base 310 includes a base 311, a cover 312 and two conductive elastic pieces 313. The base 311 has a recess 311a. The cover 312 covers the recess 311a. One end 313a of each of the conductive elastic pieces 313 is disposed outside the base 311 and soldered on one of the circuit boards 100. The other end 313b of each of the conductive elastic pieces 313 is disposed on the bottom 311b of the recess 311a.

As indicated in FIG. 2, when the cover 312 is opened, the flexible circuit board 320 can be placed in the recess 311a and touches the conductive elastic pieces 313.

As indicated in FIG. 3, when the cover 312 is closed, the cover 312 applies a force on the flexible circuit board 320 for tightly bonding the flexible circuit board 320 and the conductive elastic pieces 313.

As indicated in FIG. 1, the connecting base 310 and the light emitting elements 200 are disposed on the same surface of the circuit boards 100, and the connecting base 310 is an electronic connector. The flexible circuit board 320 is inserted into the recess 311a of the base 311 to achieve electrical connection. The circuit boards 100 can be mechanically/electrically connected through a simple locking action without using manual soldering, largely reducing the occurrence of missing solder for manual soldering and the occurrence of cracking for tin soldering. Thus, manufacturing reliability is increased.

As indicated in FIG. 2, one end 313a of each of the conductive elastic pieces 313 is disposed outside the base 311 in terms of connection. During the manufacturing process, the two conductive elastic pieces 313 are respectively soldered on the solder pads 110 of the circuit boards 100. The two conductive elastic pieces 313 are electrically connected to two electrode ends (such as the positive power supply and the negative power supply) of the light emitting elements 200 (illustrated in FIG. 1) through the internal wires of the circuit boards 100. When the flexible circuit board 320 and the connecting base 310 are locked together, the two internal wires of the flexible circuit board 320 touch the four conductive elastic pieces 313 to electrically connect the circuit boards 100 and to form the power path for serially connecting the light emitting elements 200.

In one embodiment, the connecting base 310 includes more than two conductive elastic pieces 313, and the flexible circuit board 310 can include more than two internal wires. Two sets of conductive elastic pieces 313 electrically connect two electrode ends of the light emitting element 200, and one set of conductive elastic pieces 313 is electrically connected to the grounding end of the circuit boards 100.

As indicated in FIG. 1, the circuit boards 100 are strip-shaped, and each of the connecting bases 310 is disposed near one end of the strip-shaped circuit boards 100. When the connecting bases 310 are connected through the flexible circuit board 320, two circuit boards 100 are connected to form an even longer strip-shaped structure. In one embodiment, the connecting bases 310 are disposed at two ends of each of the circuit boards 100, so that the two ends of each of the circuit boards 100 can be connected to another circuit board 100 through the power connecting set 300 of the present embodiment of the invention. Thus, the length of the lighting module 100 assembled through the power connecting set 300 of the present embodiment of the invention can be easily increased or decreased. When one particular segment of the circuit boards 100 is broken, the broken part can be easily replaced and there is no need to destructively disassemble the parts. Thus, the strip-shaped lighting module 1000 is very suitable to the LED lamp tube or the backlight module of a display.

As indicated in FIG. 1, the two connecting bases 310 of the present embodiment of the invention are disposed on the long sides 100a in the same side of the two circuit boards 100. Thus, the flexible circuit board 320 can be inserted from the long side 100a of the circuit boards 100 for convenience of assembly. In an alternative embodiment, the two connecting bases 310 can also be is disposed on two opposite short sides 100b of the two circuit boards 100. Thus, the length of the flexible circuit board 320 can further be reduced.

As indicated in FIG. 1, in terms of the structure of the flexible circuit board 320, the flexible circuit board 320 includes two first plates 321 and a second plate 322. The second plate 322 is connected to the first plates 321 to form a U-shaped structure. The first plates 321 substantially have the same length, and after the first plates 311 are inserted into the connecting base 310, the lengths of the first plates 321 exposed outside the connecting bases 310 are substantially the same. Thus, the second plate 322 maintains parallel to the long side 100a of the circuit boards 100 and will not inclined.

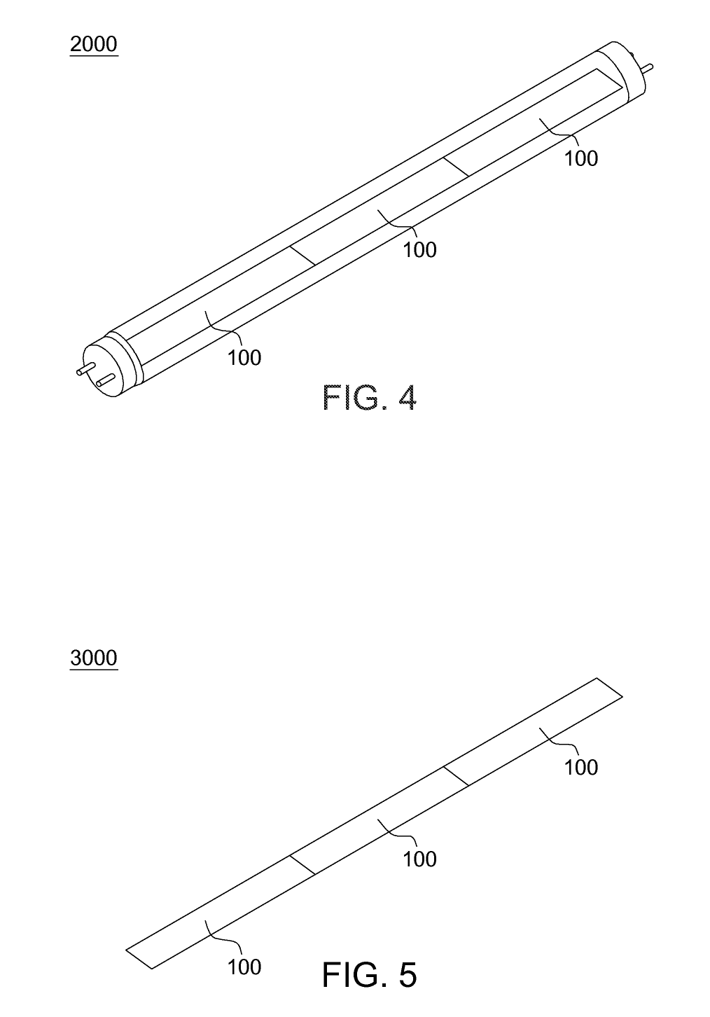

Referring to FIGS. 4 to 5. FIG. 4 shows a schematic diagram of a lamp tube 2000 according to an alternative embodiment. FIG. 5 shows a schematic diagram of a lamp bar 3000 according to an alternative embodiment. In an alternative embodiment, after the circuit boards 100 are connected through the power connecting set 300, the lighting module can be implemented with the lamp tube 2000 of FIG. 4 or the lamp bar 3000 of FIG. 5. The scope of protection of the invention is not restricted by the implementations of different types.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A lighting module, at least comprising:
two circuit boards;
two light emitting elements disposed on the circuit boards respectively; and
a power connecting set, comprising:
two connecting bases disposed on the circuit boards and electronically connected to the circuit boards respectively; and
a flexible circuit board, wherein two ends of the flexible circuit board are connected to the connecting bases for electrically connecting a power path of the circuit boards.

2. The lighting module according to claim 1, wherein each of the connecting bases is an electronic connector.

3. The lighting module according to claim 1, wherein each of the connecting bases comprises:
a base having a recess;
a cover covering the recess; and
two conductive elastic pieces, wherein one end of each of the conductive elastic pieces is disposed outside the base and soldered on one of the circuit boards, and the other end of each of the conductive elastic pieces is disposed on the bottom of the recess and touches the flexible circuit board.

4. The lighting module according to claim 1, wherein the lighting module is a lamp tube or a lamp bar.

5. The lighting module according to claim 1, wherein the connecting bases and the light emitting elements are disposed on the same surface of the circuit boards.

6. The lighting module according to claim 1, wherein the flexible circuit board is a U-shaped structure.

7. The lighting module according to claim 1, wherein the flexible circuit board comprises:
two first plates; and
a second plate connected to the first plates.

8. The lighting module according to claim 7, wherein the first plates substantially have the same length.

9. A power connecting set for connecting two circuit boards, wherein the power connecting set comprises:
two connecting bases disposed on the circuit boards and electronically connected to the circuit boards respectively; and
a flexible circuit board, wherein two ends of the flexible circuit board are connected to the connecting bases for electrically connecting a power path of the circuit boards.

10. The power connecting set according to claim 9, wherein each of the connecting bases is an electronic connector.

11. The power connecting set according to claim 9, wherein each of the connecting bases comprises:
a base having a recess;
a cover covering the recess; and
two conductive elastic pieces, wherein one end of each of the conductive elastic pieces is disposed outside the base and soldered on each of the circuit boards, and the other end of each of the conductive elastic pieces is disposed on the bottom of the recess and touches the flexible circuit board.

12. The power connecting set according to claim 9, wherein the flexible circuit board is a U-shaped structure.

13. The power connecting set according to claim 9, wherein the flexible circuit board comprises:
two first plates; and
a second plate connected to the first plates.

14. The power connecting set according to claim 13, wherein the first plates substantially have the same length.
